(19) United States
(12) Patent Application Publication
(10) Pub. No.: US 2013/0248806 A1
(43) Pub. Date: Sep. 26, 2013

(54) VARIABLE RESISTANCE MEMORY DEVICE AND METHOD FOR FABRICATING THE SAME

(71) Applicant: Choon-Kun RYU, Gyeonggi-do (KR)

(72) Inventor: Choon-Kun RYU, Gyeonggi-do (KR)

(21) Appl. No.: 13/619,653

(22) Filed: Sep. 14, 2012

(30) Foreign Application Priority Data
Mar. 23, 2012 (KR) 10-2012-0030036

(51) Int. Cl. H01L 45/00

(52) U.S. Cl. 257/4; 438/104; 257/E45.002

(57) ABSTRACT

A variable resistance memory device includes a first electrode, a second electrode, a first variable resistance layer formed over the first electrode and including at least two kinds of metal oxides, and a second variable resistance layer interposed between the first variable resistance layer and the second electrode and including a metal oxide.

### CROSS-REFERENCE TO RELATED APPLICATIONS

The present application claims priority of Korean Patent Application No. 10-2012-0030036, filed on Mar. 23, 2012, which is incorporated herein by reference in its entirety.

### BACKGROUND

1. Field

Exemplary embodiments of the present invention relate to a variable resistance memory device and a method for fabricating the same, and more particularly, to a variable resistance memory device which includes a variable resistance layer capable of changing the electrical resistance thereof by migration of ions and vacancies and a method for fabricating the same.

2. Description of the Related Art

A variable resistance memory device refers to a device which stores data, based on such a characteristic that resistance changes according to an external stimulus and switching is implemented between two different resistance states, and includes an ReRAM (resistive random access memory), a PCRAM (phase change RAM) and an STT-RAM (spin transfer torque-RAM). The variable resistance memory device has been actively researched since it can be formed to a simple structure and has various excellent properties such as nonvolatility.

Among variable resistance memory devices, the ReRAM has a structure which includes a variable resistance layer formed of a variable resistance substance, for example, a perovskite-based substance or a transition metal oxide and electrodes formed over and under the variable resistance layer. According to a voltage applied to an electrode, filament-type current paths are created or eliminated in the variable resistance layer. The variable resistance layer becomes a low resistance state when the filament-type current paths are created and becomes a high resistance state when the filament type current paths are eliminated. Switching from the high resistance state to the low resistance state is referred to as a set operation, and conversely, switching from the low resistance state to the high resistance state is referred to as a reset operation.

However, in the conventional art, since vacancies for creating the filament-type current paths are not sufficiently produced in the variable resistance layer, a resistance difference of the variable resistance layer, that is, a memory cell, according to the switching voltage becomes not so substantial. Due to this fact, it is difficult to sufficiently secure an operation margin of the variable resistance memory device, and a data retention characteristic of the variable resistance memory device is likely to deteriorate.

### SUMMARY

Embodiments of the present invention are directed to a variable resistance memory device in which the concentration of oxygen vacancies in a variable resistance layer is raised to increase a resistance difference of a memory cell according to a switching voltage, thereby augmenting an operation margin and improving a data retention characteristic, and a method for fabricating the same.

In accordance with an embodiment of the present invention, a variable resistance memory device includes: a first electrode; a second electrode; a first variable resistance layer formed over the first electrode and including at least two kinds of metal oxides; and a second variable resistance layer interposed between the first variable resistance layer and the second electrode and including a metal oxide.

In accordance with another embodiment of the present invention, a variable resistance memory device includes: a first electrode; a second electrode; a first variable resistance layer formed over the first electrode and including a metal oxide; and a second resistance variable layer interposed between the second electrode and the first variable resistance layer and including at least two kinds of metal oxides.

In accordance with yet another embodiment of the present invention, a method for fabricating a variable resistance memory device includes: forming a first electrode over a substrate; forming a first variable resistance layer including at least two kinds of metal oxides, over the first electrode; forming a second variable resistance layer including a metal oxide, over the first variable resistance layer; and forming a second electrode over the second variable resistance layer.

In accordance with still another embodiment of the present invention, a method for fabricating a variable resistance memory device includes: forming a first electrode over a substrate; forming a first variable resistance layer including a metal oxide, over the first electrode; forming a second variable resistance layer including at least two kinds of metal oxides, over the first resistance variable layer; and forming a second electrode over the second variable resistance layer.

Thanks to the above embodiments of the present invention, the concentration of oxygen vacancies in a variable resistance layer may be raised to increase a resistance difference of a memory cell according to a switching voltage, thereby augmenting an operation margin and improving a data retention characteristic.

### BRIEF DESCRIPTION OF THE DRAWINGS

FIGS. 1A to 1D are cross-sectional views showing and explaining a variable resistance memory device and a method for fabricating the same in accordance with a first embodiment of the present invention.

FIGS. 2A to 2C are cross-sectional views showing and explaining a variable resistance memory device and a method for fabricating the same in accordance with a second embodiment of the present invention.

FIGS. 3A to 3D are cross-sectional views explaining the switching mechanism of the variable resistance memory device according to the present invention.

FIG. 4 is a perspective view showing a cross point cell array structure.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

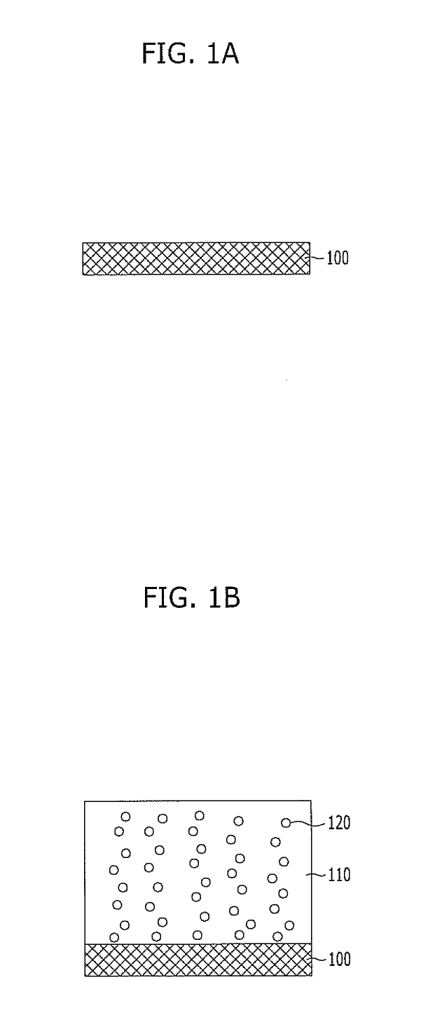

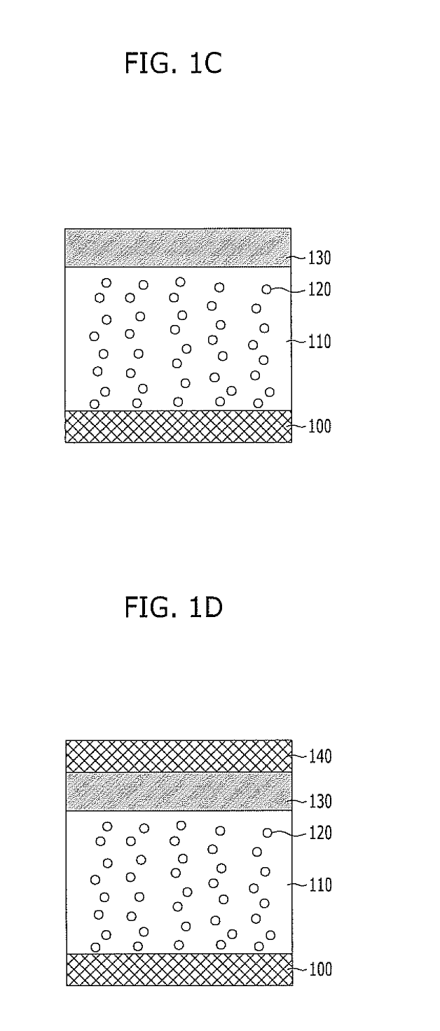

FIGS. 1A to 1D are cross-sectional views showing and explaining a variable resistance memory device and a method for fabricating the same in accordance with a first embodiment of the present invention. In particular, FIG. 1D is a cross-sectional view showing the variable resistance memory device in accordance with the first embodiment of the present invention, and FIGS. 1A to 1C are cross-sectional views showing the processes for fabricating the variable resistance memory device of FIG. 1D.

Referring to FIG. 1A, a first electrode 100 is formed on a substrate (not shown) having a predetermined underlying structure.

The first electrode 100 may be formed by depositing a metal or a metal nitride which does not react with a metal oxide included in a first variable resistance layer to be subsequently formed and is chemically stable, through physical vapor deposition (PVD). For example, the first electrode 100 may be formed through sputtering by using platinum (Pt), a titanium nitride (TiN) or a tantalum nitride (TaN) as a target. In the meantime, while not shown in the drawing, the substrate may include a peripheral circuit for driving the variable resistance memory device.

Referring to FIG. 1B, a first variable resistance layer 110 is formed on the first electrode 100.

The first variable resistance layer 110 may include at least two kinds of metal oxides and may be formed of a first metal oxide doped with a second metal oxide. A first metal is selected from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu), and a second metal as a substance different from the first metal is selected from the group consisting of calcium (Ca), Magnesium (Mg), strontium (Sr), Cobalt (Co) and nickel (Ni).

In detail, the first variable resistance layer 110 may be formed by depositing at least two kinds of metal oxides through physical vapor deposition (PVD). For example, the first variable resistance layer 110 may be formed through sputtering by using a mixture in which the second metal oxide is included by 5 to 15 atom % in the first metal oxide, as a target.

The first variable resistance layer 110 may include a plurality of oxygen vacancies 120 therein. In particular, if the second metal oxide is doped into the first metal oxide, as sites for the first metal are replaced with the second metal, the oxygen vacancies 120 are additionally created. According to this fact, because the concentration of the oxygen vacancies 120 for creating filament-type current paths is raised, a resistance difference of a memory cell according to a switching voltage may be increased.

Referring to FIG. 1C, a second variable resistance layer 130 is formed on the first variable resistance layer 110.

The second variable resistance layer 130 may serve as a tunneling barrier, and may be formed, for example, through sputtering by using the oxide of a metal selected from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu), as a target. Specifically, in the case where the second variable resistance layer 130 is formed using a substance having the same crystalline structure as the first variable resistance layer 110, since oxygen ions may easily migrate between the first and second variable resistance layers 110 and 130 in a switching operation, switching current may be reduced.

Referring to FIG. 1D, a second electrode 140 is formed on the second resistance variable layer 130.

The second electrode 140 may be formed by depositing a metal or a metal nitride which does not react with the metal oxide included in the second variable resistance layer 130 and is chemically stable, for example, through physical vapor deposition (PVD). For example, the second electrode 140 may be formed through sputtering by using platinum (Pt), a titanium nitride (TiN) or a tantalum nitride (TaN) as a target.

By the fabrication method described above, the variable resistance memory device in accordance with the first embodiment of the present invention as shown in FIG. 1D may be fabricated.

Referring to FIG. 1D, the variable resistance memory device in accordance with the first embodiment of the present invention may include the first electrode 100, the second electrode 140, the first variable resistance layer 110 interposed between the first electrode 100 and the second electrode 140 and including at least two kinds of metal oxides, and the second variable resistance layer 130 interposed between the first variable resistance layer 110 and the second electrode 140 and including a metal oxide.

Each of the first and second electrodes 100 and 140 may include a metal or a metal nitride which does not react with a metal oxide and is chemically stable.

The first variable resistance layer 110 may include the first metal oxide in which the second metal oxide may be doped, for example, by 5 to 15 atom %. For example, the first metal may be selected from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu), and the second metal as a substance different from the first metal may be selected from the group consisting of calcium (Ca), Magnesium (Mg), strontium (Sr), Cobalt (Co) and nickel (Ni).

The second variable resistance layer 130 may include the oxide of a metal selected, for example, from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu).

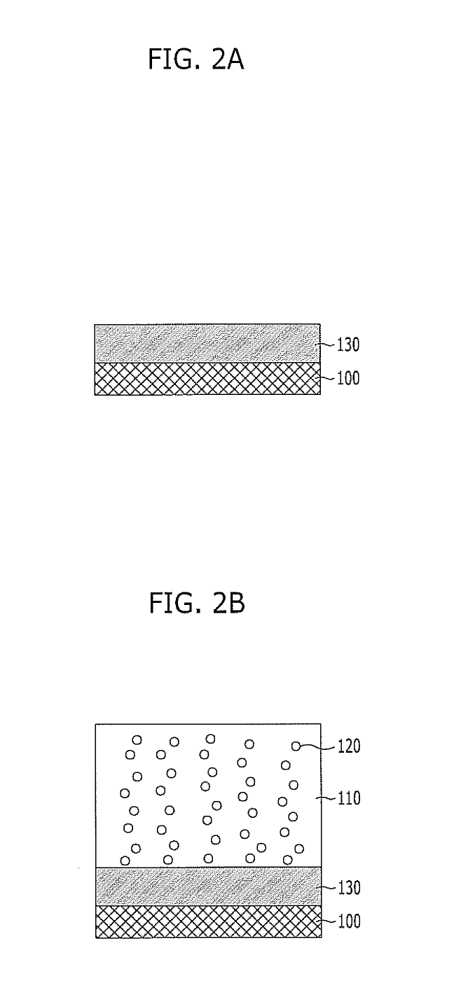

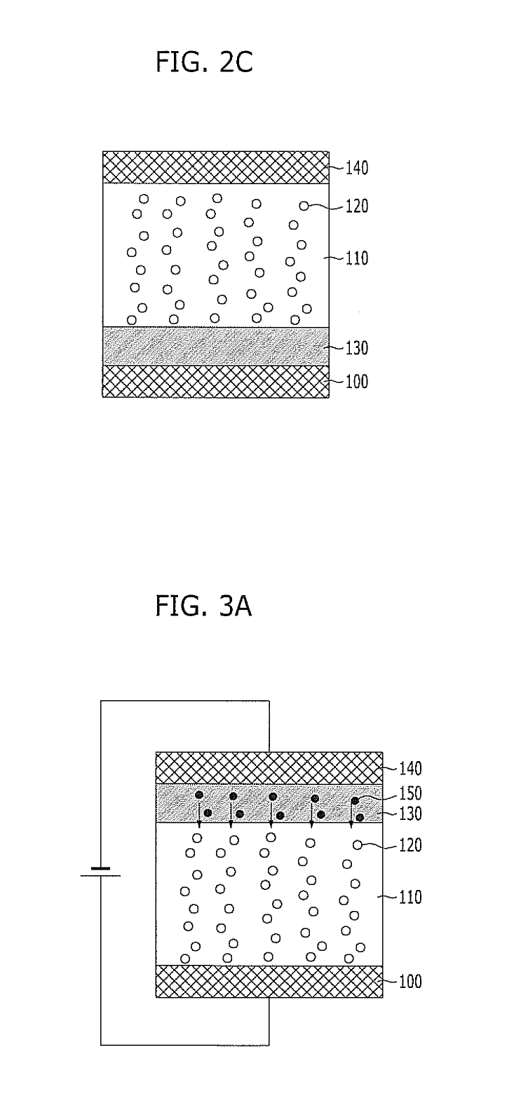

FIGS. 2A to 2C are cross-sectional views showing and explaining a variable resistance memory device and a method for fabricating the same in accordance with a second embodiment of the present invention. In describing the present embodiment, detailed descriptions for substantially the same component parts as the aforementioned first embodiment will be omitted. After the process of FIG. 1A is performed in the same manner as the first embodiment, the process of FIG. 2A is performed.

Referring to FIG. 2A, a second resistance variable layer 130 is formed on a first electrode 100.

The second variable resistance layer 130 may serve as a tunneling barrier, and may be formed, for example, through sputtering by using the oxide of a metal selected from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu), as a target.

Referring to FIG. 2B, a first variable resistance layer 110 is formed on the second variable resistance layer 130.

For example, the first variable resistance layer 110 may include at least two kinds of metal oxides and may be formed through sputtering by using a mixture in which a second metal oxide may be included by 5 to 15 atom % in a first metal oxide, as a target. A first metal may be selected, for example, from the group consisting of zirconium (Zr), hafnium (Hf), magnesium (Mg), manganese (Mn), nickel (Ni), aluminum (Al), cerium (Ce), cobalt (Co), chrome (Cr), tungsten (W) and copper (Cu), and a second metal as a substance different from the first metal may be selected from the group consisting of calcium (Ca), Magnesium (Mg), strontium (Sr), Cobalt (Co) and nickel (Ni). The first resistance variable layer 110 may include a plurality of oxygen vacancies 120 therein.

Referring to FIG. 2C, a second electrode 140 is formed on the first resistance variable layer 110.

The second electrode 140 may be formed, for example, through sputtering by using a metal or a metal nitride which does not react with the metal oxides included in the first resistance variable layer 110 and is chemically stable, for example, platinum (Pt), a titanium nitride (TiN) or a tantalum nitride (TaN), as a target.

The second embodiment described just above is different from the first embodiment in that the second resistance variable layer 130 is formed earlier than the first resistance variable layer 110.

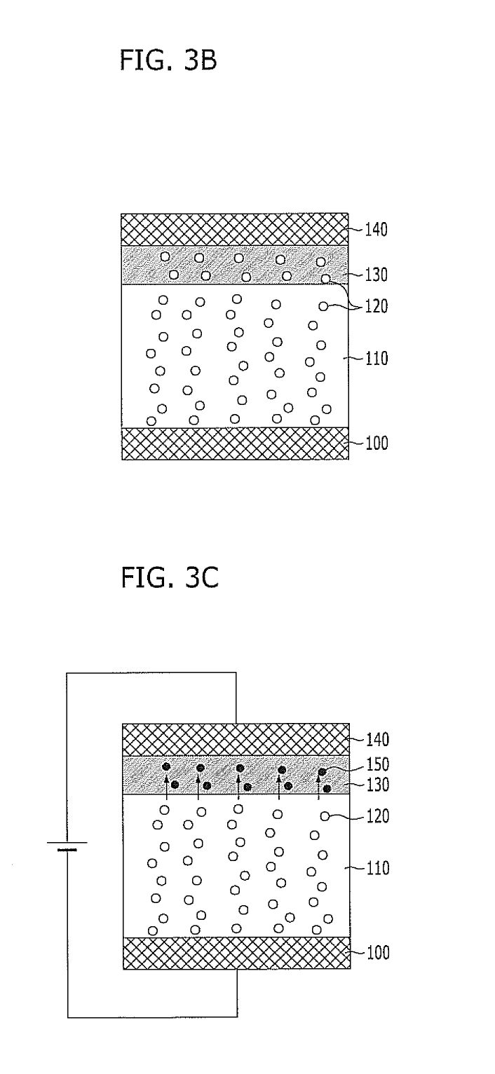

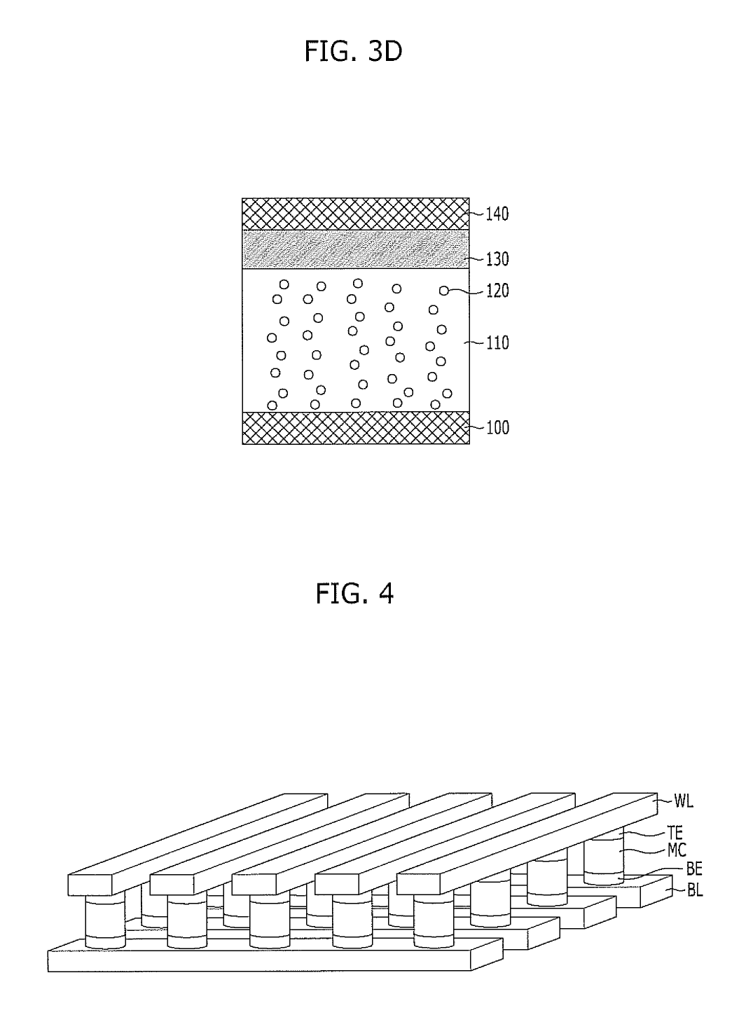

FIGS. 3A to 3D are cross-sectional views explaining the switching mechanism of the variable resistance memory device according to the present invention.

Referring to FIG. 3A, in the case where a positive (+) voltage is applied to the first electrode 100 that is formed under the first variable resistance layer 110 with a high concentration of the oxygen vacancies 120, oxygen ions (O²⁻) 150 in the second variable resistance layer 130 migrate to the first variable resistance layer 110. According to this fact, oxygen vacancies 120 may be created in the second variable resistance layer 130.

Referring to FIG. 3B, as the oxygen vacancies 120 are created in the second variable resistance layer 130, filament-type current paths formed by the oxygen vacancies 120 are produced between the first electrode 100 and the second electrode 140. According to this fact, the first and second variable resistance layers 110 and 130, that is, a memory cell is converted from a high resistance state (HRS) into a low resistance state (LRS).

Referring to FIG. 3C, in the case where a positive (+) voltage is applied to the second electrode 140 that forms over the second variable resistance layer 130 in which the oxygen vacancies 120 are created, oxygen ions 150 in the first variable resistance layer 110 migrate to the second variable resistance layer 130. Therefore, the oxygen vacancies 120 in the second variable resistance layer 130 may be filled with the oxygen ions 150.

Referring to FIG. 3D, as the oxygen vacancies 120 in the second variable resistance layer 130 are filled with the oxygen ions 150, the filament-type current paths created between the first electrode 100 and the second electrode 140 are eliminated. According to this fact, the first and second variable resistance layers 110 and 130, that is, the memory cell is converted from a low resistance state (LRS) into a high resistance state (HRS).

In the case of the variable resistance memory device in accordance with the embodiment of the present invention, as the first variable resistance layer 110 may be formed of the first metal oxide (for example, ZrO₂) that may be doped with the second metal oxide (for example, CaO), the first variable resistance layer 110 includes the oxygen vacancies of a high concentration. Due to this fact, as an amount of the oxygen ions 150 migrating between the first variable resistance layer 110 and the second variable resistance layer 130 according to a switching voltage increases, a changing amount of the filament-type current paths produced between the first electrode 100 and the second electrode 140 increases. As a result, as a resistance difference between the high resistance state (HRS) and the low resistance state (LRS) of the memory cell increases, an operation margin of the variable resistance memory device may be augmented.

FIG. 4 is a perspective view showing a cross point cell array structure.

Referring to FIG. 4, the variable resistance memory device in accordance with the embodiments of the present invention may be formed to have a cross point cell array structure. The cross point cell array structure refers to a structure that memory cells MC are disposed at crossing points between a plurality of bit lines BL parallel to one another and a plurality of word lines WL crossing with the bit lines BL and parallel to one another, and selection elements (not shown), for example, transistors or diodes may be connected to the top parts or bottom parts of the respective memory cells MC.

The memory cells MC may include a variable resistance layer that changes resistance according to an applied voltage or current to allow the variable resistance layer to be switched between at least two resistance states. The bottom parts of the memory cells MC may be connected with the bit lines BL through bottom electrodes BE, and the top parts of the memory cells MC may be connected with the word lines WL through top electrodes TE.

As is apparent from the above descriptions, in the variable resistance memory device and the method for fabricating the same according to the first and second embodiments of the present invention, since a variable resistance layer is formed of a first metal oxide which is doped with a second metal oxide, the concentration of oxygen vacancies formed in the variable resistance layer may be raised. As a consequence, a resistance difference between a high resistance state and a low resistance state of a memory cell according to a switching voltage is increased, whereby an operation margin of the resistance variable memory device may be augmented and a data retention characteristic may be improved.

While the present invention has been described with respect to the specific embodiments, it will be apparent to those skilled in the art that various changes and modifications may be made without departing from the spirit and scope of the invention as defined in the following claims.

What is claimed is:

1. A variable resistance memory device comprising:
a first electrode;
a second electrode;
a first variable resistance layer formed over the first electrode and including at least two kinds of metal oxides; and
a second variable resistance layer interposed between the first variable resistance layer and the second electrode and including a metal oxide.

2. The variable resistance memory device of claim 1,
wherein the first variable resistance layer includes a first metal oxide which is doped with a second metal oxide,
wherein a first metal is selected from the group consisting of zirconium, hafnium, magnesium, manganese, nickel, aluminum, cerium, cobalt, chrome, tungsten and copper, and
wherein a second metal comprising a substance different from the first metal is selected from the group consisting of calcium, magnesium, strontium, cobalt and nickel.

3. The variable resistance memory device of claim 1, wherein the second variable resistance layer includes an oxide of a metal selected from the group consisting of zirconium, hafnium, magnesium, manganese, nickel, aluminum, cerium, cobalt, chrome, tungsten and copper.

4. The variable resistance memory device of claim 1, wherein each of the first and second electrodes includes a metal or a metal nitride which does not react with a metal oxide.

5. The variable resistance memory device of claim 2, wherein the first resistance variable layer includes the second metal oxide by 5 to 15 atom %.

6. A variable resistance memory device comprising:
a first electrode;
a second electrode;
a first variable resistance layer formed over the first electrode and including a metal oxide; and
a second resistance variable layer interposed between the second electrode and the first variable resistance layer and including at least two kinds of metal oxides.

7. The variable resistance memory device of claim 6,
wherein the second variable resistance layer includes a first metal oxide which is doped with a second metal oxide,
wherein a first metal is selected from the group consisting of zirconium, hafnium, magnesium, manganese, nickel, aluminum, cerium, cobalt, chrome, tungsten and copper, and
wherein a second metal comprising a substance different from the first metal is selected from the group consisting of calcium, magnesium, strontium, cobalt and nickel.

8. The variable resistance memory device of claim 6, wherein the first variable resistance layer includes an oxide of a metal selected from the group consisting of zirconium, hafnium, magnesium, manganese, nickel, aluminum, cerium, cobalt, chrome, tungsten and copper.

9. The variable resistance memory device of claim 6, wherein each of the first and second electrodes includes a metal or a metal nitride which does not react with a metal oxide.

10. The variable resistance memory device of claim 7, wherein the second variable resistance layer includes the second metal oxide by 5 to 15 atom %.

11. A method for fabricating a variable resistance memory device, comprising:
forming a first electrode over a substrate;
forming a first variable resistance layer including at least two kinds of metal oxides, over the first electrode;
forming a second variable resistance layer including a metal oxide, over the first variable resistance layer; and
forming a second electrode over the second variable resistance layer.

12. The method of claim 11,
wherein the first variable resistance layer is formed of a first metal oxide which is doped with a second metal oxide,
wherein a first metal is selected from the group consisting of zirconium, hafnium, magnesium, manganese, nickel, aluminum, cerium, cobalt, chrome, tungsten and copper, and
wherein a second metal comprising a substance different from the first metal is selected from the group consisting of calcium, magnesium, strontium, cobalt and nickel.

13. The method of claim 11, wherein the second variable resistance layer is formed of an oxide of a metal selected from the group consisting of zirconium, hafnium, magnesium, manganese, nickel, aluminum, cerium, cobalt, chrome, tungsten and copper.

14. The method of claim 11, wherein each of the first and second electrodes is formed of a metal or a metal nitride which does not react with a metal oxide.

15. The method of claim 11, wherein each of the first and second variable resistance layers is formed through sputtering.

16. The method of claim 11, wherein each of the first and second electrodes is formed through sputtering.

17. The method of claim 12, wherein the first variable resistance layer includes the second metal oxide by 5 to 15 atom %.

18. A method for fabricating a variable resistance memory device, comprising:
forming a first electrode over a substrate;
forming a first variable resistance layer including a metal oxide, over the first electrode;
forming a second variable resistance layer including at least two kinds of metal oxides, over the first resistance variable layer; and
forming a second electrode over the second variable resistance layer.

19. The method of claim 18,
wherein the second variable resistance layer is formed of a first metal oxide which is doped with a second metal oxide,
wherein a first metal is selected from the group consisting of zirconium, hafnium, magnesium, manganese, nickel, aluminum, cerium, cobalt, chrome, tungsten and copper, and
wherein a second metal comprising a substance different from the first metal is selected from the group consisting of calcium, magnesium, strontium, cobalt and nickel.

20. The method of claim 18, wherein the first variable resistance layer is formed of an oxide of a metal selected from the group consisting of zirconium, hafnium, magnesium, manganese, nickel, aluminum, cerium, cobalt, chrome, tungsten and copper.

21. The method of claim 18, wherein each of the first and second electrodes is formed of a metal or a metal nitride which does not react with a metal oxide.

22. The method of claim 18, wherein each of the first and second variable resistance layers is formed through sputtering.

23. The method of claim 18, wherein each of the first and second electrodes is formed through sputtering.

24. The method of claim 19, wherein the second variable resistance layer includes the second metal oxide by 5 to 15 atom %.
